(19) United States
(12) Patent Application Publication
(10) Pub. No.: US 2021/0321536 A1
(43) Pub. Date: Oct. 14, 2021

(54) THIN HEAT SINK STRUCTURE

(71) Applicant: THERMASOL TECHNOLOGY CO., LTD., Tainan City (TW)

(72) Inventor: I-MING LIU, TAINAN CITY (TW)

(21) Appl. No.: 16/845,775

(22) Filed: Apr. 10, 2020

(51) Int. Cl. H05K 7/20

(52) U.S. Cl. CPC H05K 7/20272; H05K 7/20409

(57) ABSTRACT

A thin heat sink structure includes a housing and at least one heat dissipation plate. The housing is assembled from a first housing portion and a second housing portion and is formed therein with a receiving space. The heat dissipation plate is provided in the receiving space and is formed with at least one hollow flow channel by stamping. The flow channel is in communication with the first housing portion and the second housing portion. Two heat dissipation plates can be stacked in the receiving space in such a way that the two flow channels are linearly or angularly offset with respect to and overlap each other, and that the overlapping portions of the two flow channels form a hollow portion in communication with the two housing portions. The thin heat sink structure can be made into a large heat sink with high heat dissipation efficiency.

### BACKGROUND OF THE INVENTION

### 1. Technical Field

The present invention relates to a thin heat sink that can be manufactured with ease and dissipate heat with great efficiency.

### 2. Description of Related Art

Nowadays, electronic products such as desktop or laptop computers tend to generate high heat during operation, and it is imperative to dissipate this heat because it may compromise the efficiency and quality of the work to be done with such a product. As the space in an electronic product that can be used to accommodate a heat dissipation device, e.g., a heat sink, has a limitation in height, a heat sink must be thin but still capable of maintaining optimal heat dissipation efficiency.

For example, Taiwan Utility Model Patent No. M339716, entitled “ASSEMBLY-TYPE HEAT DISSIPATION PLATE STRUCTURE” and published on Sep. 1, 2008, discloses a heat sink that includes a base body made of aluminum, which dissipates heat rapidly, and a plurality of heat dissipation fins connected to a top portion of the base body, wherein: the base body is assembled from an upper portion and a lower portion, both formed by stamping; the base body is provided therein with a corrugated plate configured for fluid guiding purposes or as a capillary device; and the base body, the heat dissipation fins, and the corrugated plate are soldered together to form a single unit.

The heat sink disclosed in the '716 patent cannot be made thinner because the corrugated plate (or capillary device) in the stamped base body makes it impossible to do so. Moreover, the heat sink does not have adequate structural strength and can only provide limited heat dissipation.

Taiwan Utility Model Patent No. M397545, entitled “STACK-TYPE HEAT SINK STRUCTURE” and published on Feb. 1, 2011, discloses another heat sink, which is composed of a plurality of heat dissipation plates stacked together, wherein: the heat dissipation plates include two cover plates with corresponding receiving spaces; the outer wall of each receiving space is provided with at least one connecting portion; each connecting portion is formed with a through hole in communication with the corresponding receiving space; the two cover plates are stacked up to form a cavity therebetween; and in order to enhance heat transfer through the heat dissipation plates, each receiving space is provided with a plurality of protruding portions that extend into the receiving space and are formed by stamping, or a capillary structure is provided in the cavity.

Since the heat dissipation plates disclosed in the '545 patent have stamped hollow bumps, the area of contact with the heat source is reduced, which leads to inefficient heat dissipation.

Taiwan Utility Model Patent No. M416323, entitled “HEAT DISSIPATION DEVICE AND HEAT DISSIPATION PLATE THEREOF” and published on Nov. 11, 2011, discloses yet another heat sink, which includes a heat dissipation plate, a first end cap fixedly connected to the heat dissipation plate, and a second end cap fixedly connected to the heat dissipation plate.

As the flat tube-shaped heat sink disclosed in the '323 patent is made by aluminum extrusion, and it is not only difficult but also expensive to make a large thin heat sink by aluminum extrusion, much is left to be desired in terms of production.

### BRIEF SUMMARY OF THE INVENTION

In view of the aforementioned drawbacks of the existing thin heat sinks, the present invention provides a thin heat sink structure that includes a housing and at least one heat dissipation plate. The housing includes and is assembled from a first housing portion and a second housing portion. The housing is formed therein with a receiving space. The heat dissipation plate is provided in the receiving space and is formed with at least one hollow flow channel. The flow channel is in communication with the first housing portion and the second housing portion.

Preferably, there are at least two heat dissipation plates, and the two heat dissipation plates are stacked in the receiving space in such a way that the two flow channels are linearly or angularly offset with respect to and overlap each other, and that the overlapping portions of the two flow channels form a hollow portion in communication with the first housing portion and the second housing portion.

Preferably, the two heat dissipation plates are stacked in such a way that the two flow channels are at 90° with (i.e., perpendicular to) each other or at 180° with each other (i.e., one turned over or upside down with respect to the other).

Preferably, the at least one flow channel of each heat dissipation plate is one or an arbitrary combination of a continuous back-and-forth wavy-shaped flow channel, a continuous and slanting back-and-forth wavy-shaped flow channel, a plurality of rows of slantingly arranged and spaced-apart H-shaped flow channels, a continuous back-and-forth curvy-shaped flow channel, and a continuous circular spiral-shaped flow channel.

Preferably, the first housing portion is fixedly provided with a plurality of heat dissipation fins, and the second housing portion is joined to a heat source.

Preferably, the flow channel of one of the at least two heat dissipation plates has one end configured as an input end, and the input end is in communication with a through hole of the housing so that a working fluid can be input into the input end and not only flow in the flow channels, but also contact the first housing portion and the second housing portion.

Preferably, the flow channel of the other heat dissipation plate has one end configured as an output end, and the output end is in communication with another through hole of the housing so that the working fluid can be output through the output end.

Preferably, the first housing portion is fixedly provided with a plurality of heat dissipation fins, the second housing portion is joined to a heat source, and the input end and the output end are connected to a pump so that the working fluid can be circulated between the interior of the housing and the pump.

Preferably, four housings are connected to jointly form a vertical structure, and the receiving spaces in the four housings are in communication with one another to form a circulatory heat dissipation loop.

Preferably, the first housing portion, the second housing portion, and the at least one heat dissipation plate are soldered together, and the flow channel of the heat dissipation plate is formed by stamping.

The foregoing technical features have the following advantages:

1. As the flow channel of each heat dissipation plate is formed by stamping, a large thin heat sink can be made at a low cost, without the production difficulties associated with aluminum extrusion.

2. By stacking two heat dissipation plates in the receiving space and arranging their flow channels in a linearly or angularly offset and overlapping manner, the strength of the entire heat sink is enhanced, and a hollow portion is formed by the overlapping portions of the two flow channels so that a working fluid can circulate through the hollow portion and come into contact, and thereby exchange heat, with the first housing portion and the second housing portion to dissipate heat efficiently.

3. By configuring one end of a flow channel as an input end, which is in communication with a through hole of the housing, a vacuum can be created in the receiving space of the housing by drawing air out of the receiving space through a sealing tube in the input end, and a working fluid can be injected into the vacuum, before the sealing tube is sealed to form a closed heat sink structure that dissipates heat through internal circulation of the working fluid and that can be adapted to meet different heat dissipation needs.

4. The flow channel of a heat dissipation plate may have one end in communication with a through hole of the housing and connected to an input end, and the flow channel of another heat dissipation plate may have one end in communication with another through hole of the housing and connected to an output end so that a working fluid can be injected into the input end and output through the output end, forming an open heat sink structure that dissipates heat through extended external circulation of the working fluid and that can also be adapted to meet different heat dissipation needs.

### BRIEF DESCRIPTION OF THE SEVERAL VIEWS OF THE DRAWINGS

FIG. 1 is an exploded perspective of the first embodiment of the present invention.

FIG. 2 is an assembled sectional view of the first embodiment of the invention.

FIG. 3 is a front view of the heat dissipation plate in the first embodiment of the invention.

FIG. 4 schematically shows a state of use of the first embodiment of the invention as a closed heat sink.

FIG. 5 is an exploded perspective view of the second embodiment of the invention.

FIG. 6 is an assembled sectional view of the second embodiment of the invention.

FIG. 7 schematically shows that the two heat dissipation plates in the second embodiment of the invention are stacked with their flow channels angularly offset with respect to and overlapping each other.

FIG. 8 is an exploded perspective view of the third embodiment of the invention.

FIG. 9 schematically shows that the two heat dissipation plates in the third embodiment of the invention are stacked with their flow channels angularly offset with respect to and overlapping each other.

FIG. 10 is an exploded perspective view of the fourth embodiment of the invention.

FIG. 11 schematically shows that the two heat dissipation plates in the fourth embodiment of the invention are stacked with their flow channels linearly offset with respect to and overlapping each other.

FIG. 12 is an exploded perspective view of the fifth embodiment of the invention.

FIG. 13 schematically shows that the two heat dissipation plates in the fifth embodiment of the invention are stacked with their flow channels angularly offset with respect to and overlapping each other.

FIG. 14 is an exploded perspective view of the sixth embodiment of the invention.

FIG. 15 schematically shows that the two heat dissipation plates in the sixth embodiment of the invention are stacked with their flow channels linearly offset with respect to and overlapping each other.

FIG. 16 is an exploded perspective view of the seventh embodiment of the invention.

FIG. 17 schematically shows that the two heat dissipation plates in the seventh embodiment of the invention are stacked with their flow channels angularly offset with respect to and overlapping each other.

FIG. 18 is an exploded perspective view of the eighth embodiment of the invention.

FIG. 19 schematically shows that the two heat dissipation plates in the eighth embodiment of the invention are stacked with their flow channels angularly offset with respect to and overlapping each other.

FIG. 20 schematically shows a state of use of the eighth embodiment of the invention as an open heat sink.

FIG. 21 schematically shows a state of use of the ninth embodiment of the invention as a closed heat sink.

FIG. 22 is an assembled sectional view of the ninth embodiment of the invention.

FIG. 23 schematically shows a state of use of the tenth embodiment of the invention as a closed heat sink.

FIG. 24 is an assembled sectional view of the tenth embodiment of the invention.

### DETAILED DESCRIPTION OF THE INVENTION

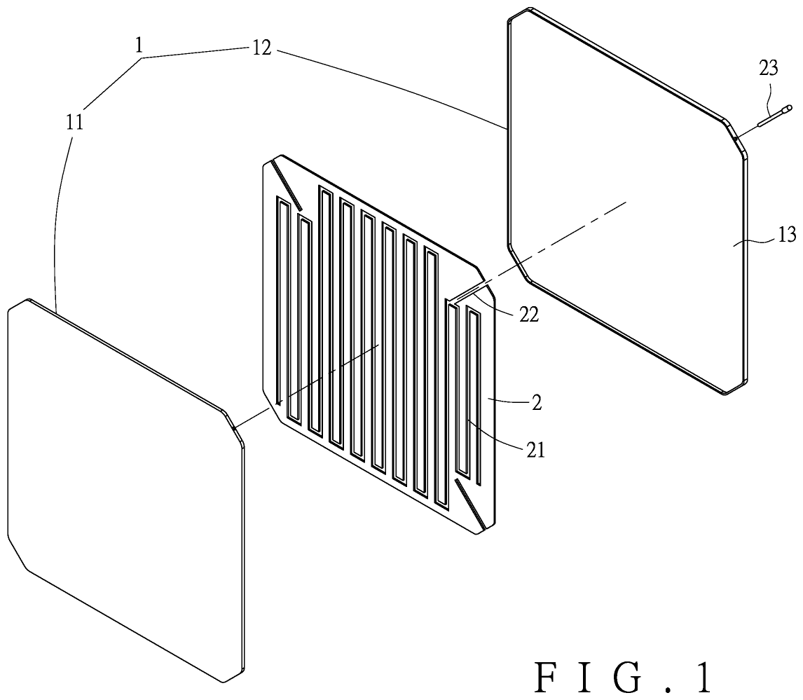

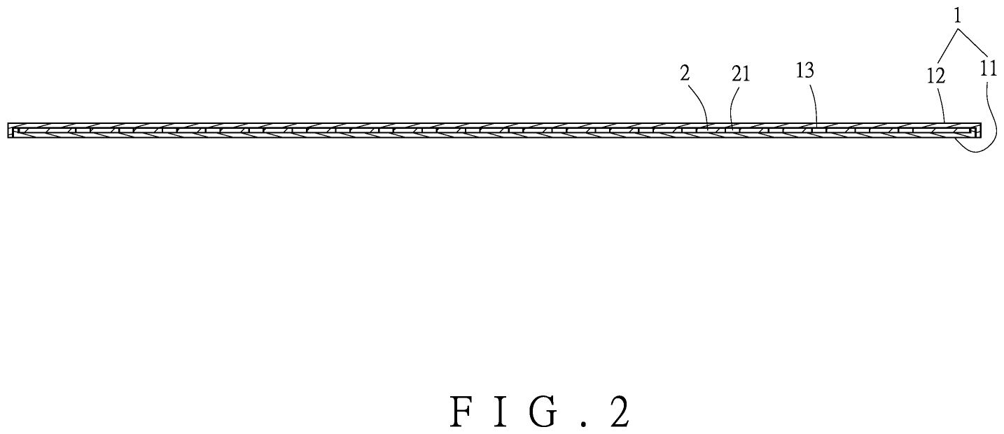

Referring to FIG. 1 and FIG. 2, the first embodiment of the present invention includes a housing 1 and at least one heat dissipation plate 2.

The housing 1 includes a first housing portion 11 and a second housing portion 12, which are soldered together along with the heat dissipation plate 2. The housing 1 is formed therein with a closed receiving space 13.

The heat dissipation plate 2 is provided in the receiving space 13. The heat dissipation plate 2 is formed with a hollow flow channel 21 by stamping. The flow channel 21 has a predetermined geometric shape, which in this embodiment is a continuous back-and-forth wavy shape. The flow channel 21 is in communication with the first housing portion 11 and the second housing portion 12. One end of the flow channel 21 is configured as an input end 22 and is in communication with a through hole of the housing 1. A sealing tube 23 is inserted into the input end 22 so that the air in the receiving space 13 can be drawn out through the sealing tube 23 to create a vacuum into which a working fluid is subsequently injected. The sealing tube 23 is sealed after injection of the working fluid. The working fluid is a refrigerant intended to flow in the flow channel 21.

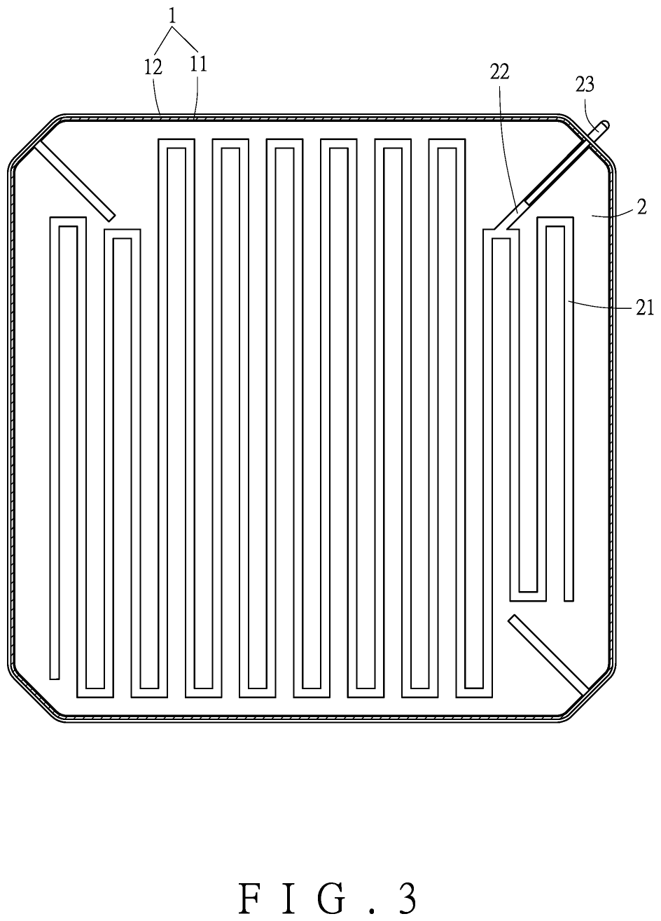

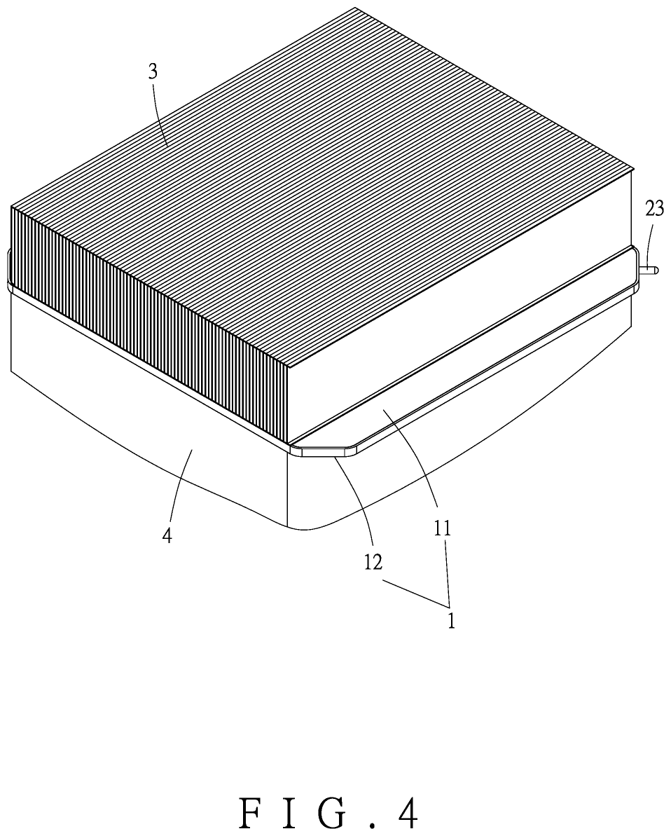

To use this embodiment as a closed heat sink, referring to FIG. 3 and FIG. 4, an outer surface of the first housing portion 11 is fixedly provided with a plurality of heat dissipation fins 3, and an outer surface of the second housing portion 12 is joined to a heat source 4 from which heat is to be dissipated. The heat generated by the heat source 4 is transmitted through the second housing portion 12 to the working fluid in the flow channel 21 as heat exchange takes place between the heat source 4 and the working fluid. Once the heat is accumulated in the working fluid, turbulent flow is generated in the flow channel 21 (which has a continuous back-and-forth wavy shape), and the working fluid is circulated between the first housing portion 11 and the second housing portion 12 and can therefore make sufficient contact with the first housing portion 11 to conduct the heat to the heat dissipation fins 3 on the outer surface of the first housing portion 11. Then, by heat exchange between the heat dissipation fins 3 and the relatively low-temperature ambient air, the heat of the heat source 4 is eventually dissipated to the surroundings.

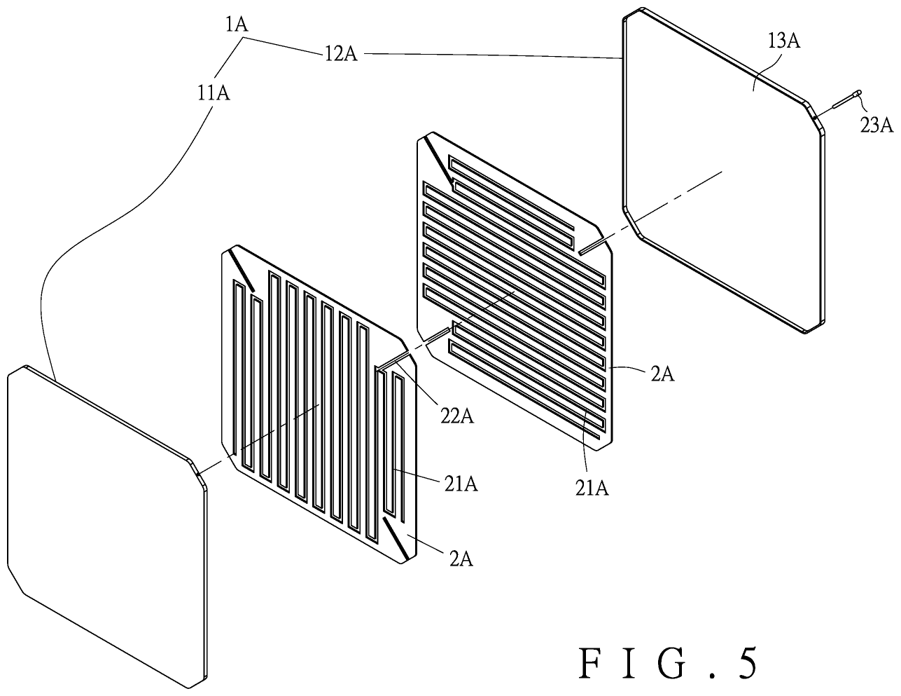

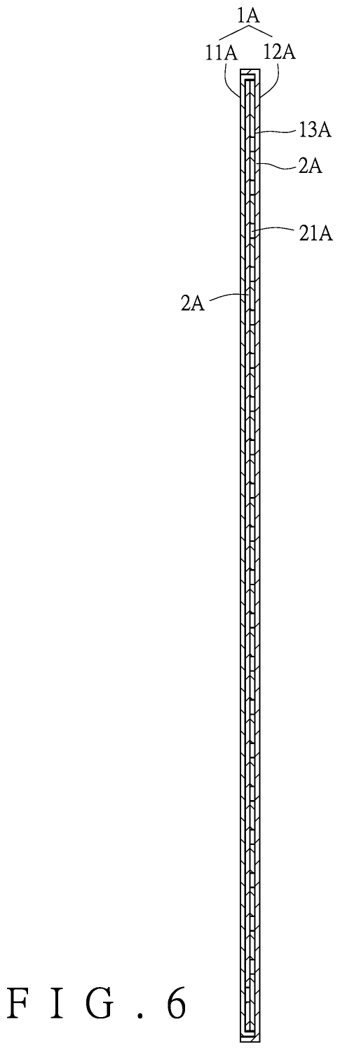

Please refer FIG. 5 and FIG. 6 for the second embodiment of the present invention.

The second embodiment includes a housing 1A and at least two heat dissipation plates 2A. The housing 1A includes a first housing portion 11A and a second housing portion 12A, which are soldered together along with the heat dissipation plates 2A. The housing 1A is formed therein with a closed receiving space 13A.

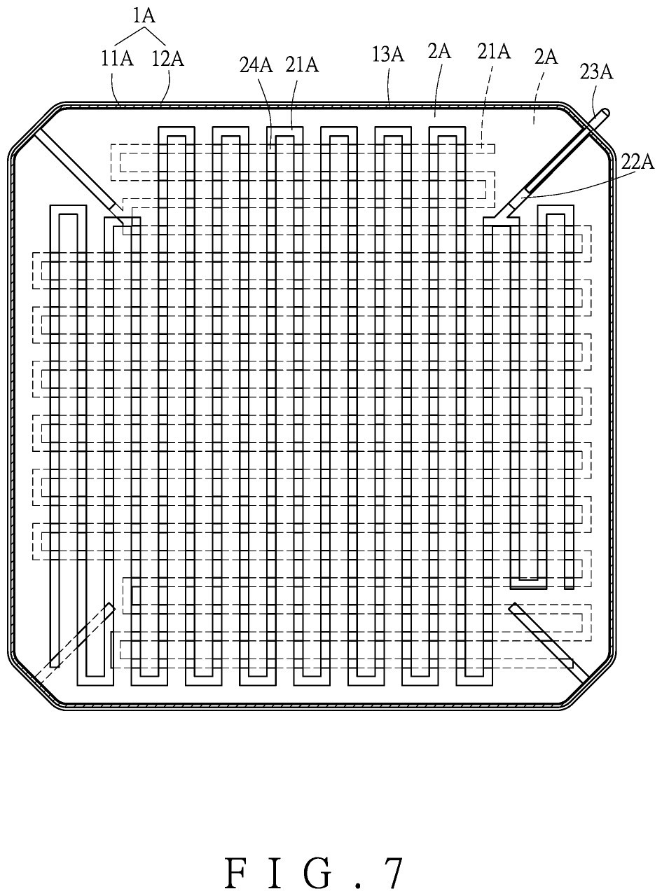

The two heat dissipation plates 2A are stacked in the receiving space 13A in such a way that their flow channels 21A are angularly offset with respect to and overlap each other. The two heat dissipation plates 2A are each formed with a hollow flow channel 21A by stamping, and each of the two flow channels 21A has a continuous back-and-forth wavy shape. The two heat dissipation plates 2A are so stacked that the two flow channels 21A are perpendicular to and overlap each other, and that the overlapping portions of the two flow channels 21A form a hollow portion 24A as shown in FIG. 7. The hollow portion 24A is in communication with the first housing portion 11A and the second housing portion 12A. One of the flow channels 21A has one end configured as an input end 22A, which is in communication with a through hole of the housing 1A. A sealing tube 23A is inserted into the input end 22A so that a working fluid can be injected through the sealing tube 23A into the input end 22A before the sealing tube 23A is sealed.

To use this embodiment as a closed heat sink, referring to FIG. 5 and FIG. 7, an outer surface of the first housing portion 11A is fixedly provided with a plurality of heat dissipation fins (see FIG. 4), and an outer surface of the second housing portion 12A is joined to a heat source from which heat is to be dissipated (see also FIG. 4). The heat generated by the heat source can be dissipated through the working fluid in the housing 1A in the same way as in the first embodiment; the heat dissipation process, therefore, will not be described repeatedly.

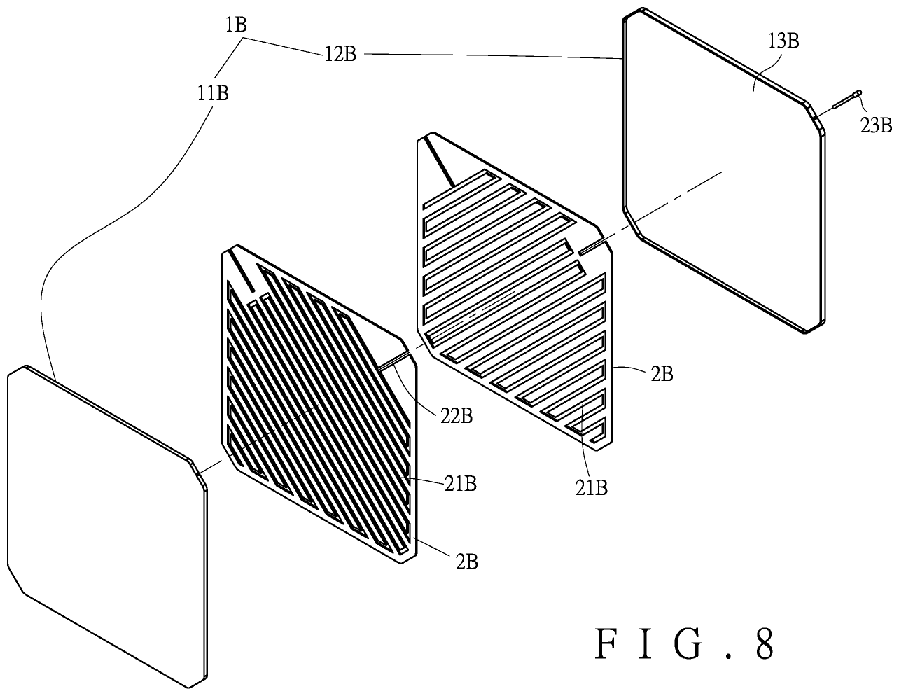

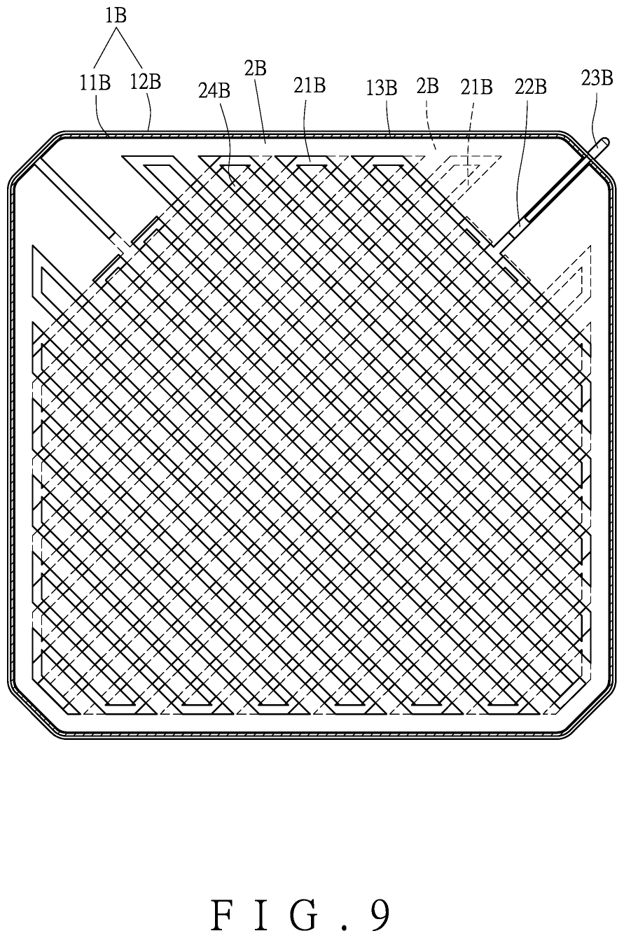

Please refer FIG. 8 and FIG. 9 for the third embodiment of the present invention.

The third embodiment includes a housing 1B and at least two heat dissipation plates 2B. The housing 1B includes a first housing portion 11B and a second housing portion 12B, which are soldered together along with the heat dissipation plates 2B. The housing 1B is formed therein with a closed receiving space 13B.

The two heat dissipation plates 2B are stacked in the receiving space 13B in such a way that their flow channels 21B are angularly offset with respect to and overlap each other. The two heat dissipation plates 2B are each formed with a hollow flow channel 21B by stamping, and each of the two flow channels 21B has a continuous and slanting back-and-forth wavy shape. The two heat dissipation plates 2B are so stacked that the two flow channels 21B are perpendicular to and overlap each other, and that the overlapping portions of the two flow channels 21B form a hollow portion 24B. The hollow portion 24B is in communication with the first housing portion 11B and the second housing portion 12B. One of the flow channels 21B has one end configured as an input end 22B, which is in communication with a through hole of the housing 1B. A sealing tube 23B is inserted into the input end 22B so that a working fluid can be injected through the sealing tube 23B into the input end 22B before the sealing tube 23B is sealed.

To use this embodiment as a closed heat sink, with continued reference to FIG. 8 and FIG. 9, an outer surface of the first housing portion 11B is fixedly provided with a plurality of heat dissipation fins (see FIG. 4), and an outer surface of the second housing portion 12B is joined to a heat source from which heat is to be dissipated (see also FIG. 4). The heat generated by the heat source can be dissipated through the working fluid in the housing 1B in the same way as in the first embodiment; the heat dissipation process, therefore, will not be described repeatedly.

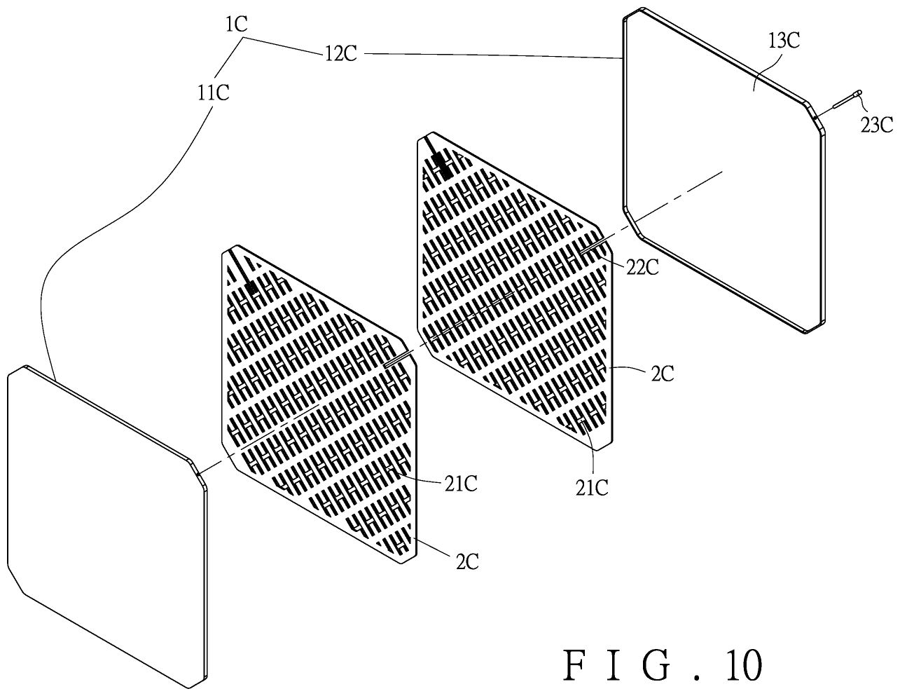

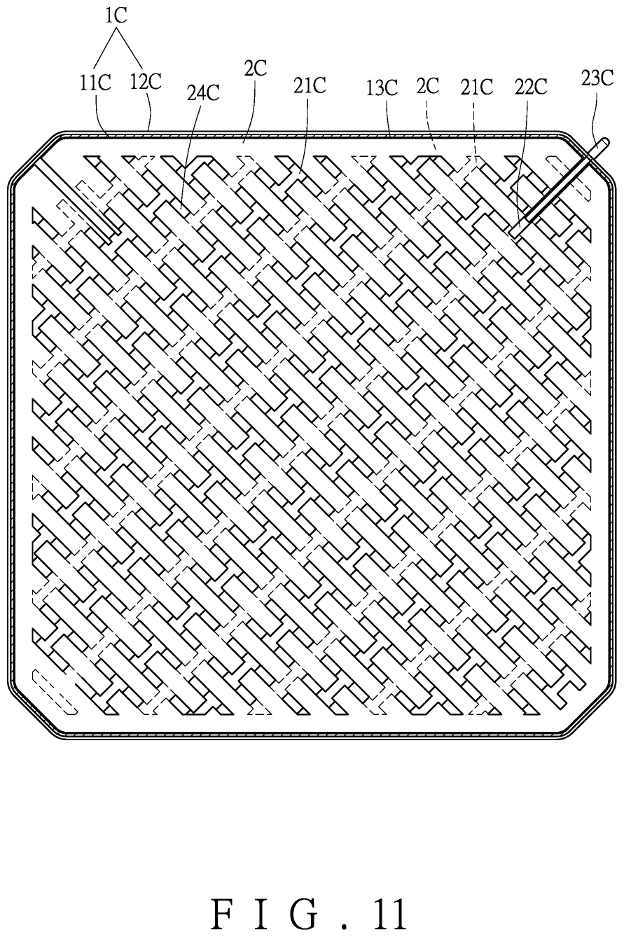

Please refer FIG. 10 and FIG. 11 for the fourth embodiment of the present invention.

The fourth embodiment includes a housing 1C and at least two heat dissipation plates 2C. The housing 1C includes a first housing portion 11C and a second housing portion 12C, which are soldered together along with the heat dissipation plates 2C. The housing 1C is formed therein with a closed receiving space 13C.

The two heat dissipation plates 2C are stacked in the receiving space 13C in such a way that their flow channels 21C are linearly offset with respect to and overlap each other. The two heat dissipation plates 2C are each formed with a plurality of hollow flow channels 21C by stamping, and the flow channels 21B of each heat dissipation plate 2C are a plurality of rows of slantingly arranged and spaced-apart H-shaped flow channels. The two heat dissipation plates 2C are so stacked that the plural rows of flow channels 21C of one heat dissipation plate 2C are parallel to, are linearly offset from, and overlap the plural rows of flow channels 21C of the other heat dissipation plate 2C in a direction perpendicular to the rows of flow channels 21C, and that the overlapping portions of the flow channels 21C form a hollow portion 24C. The hollow portion 24C is in communication with the first housing portion 11C and the second housing portion 12C. One flow channel 21C of one of the heat dissipation plates 2C has one end configured as an input end 22C, which is in communication with a through hole of the housing 1C. A sealing tube 23C is inserted into the input end 22C so that a working fluid can be injected through the sealing tube 23C into the input end 22C before the sealing tube 23C is sealed.

To use this embodiment as a closed heat sink, with continued reference to FIG. 10 and FIG. 11, an outer surface of the first housing portion 11C is fixedly provided with a plurality of heat dissipation fins (see FIG. 4), and an outer surface of the second housing portion 12C is joined to a heat source from which heat is to be dissipated (see also FIG. 4). The heat generated by the heat source can be dissipated through the working fluid in the housing 1C in the same way as in the first embodiment; the heat dissipation process, therefore, will not be described repeatedly.

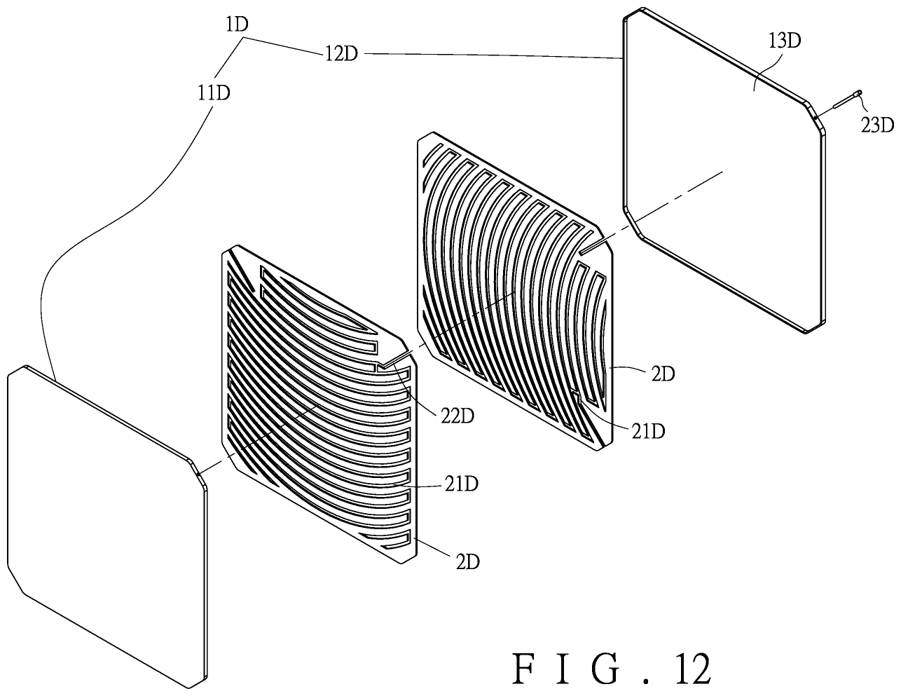

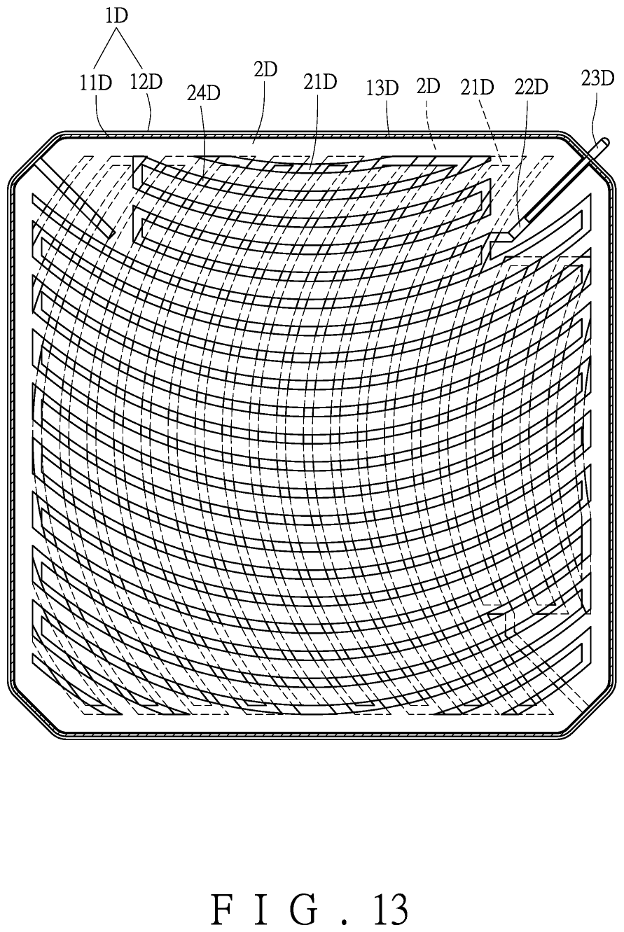

Please refer FIG. 12 and FIG. 13 for the fifth embodiment of the present invention.

The fifth embodiment includes a housing 1D and at least two heat dissipation plates 2D. The housing 1D includes a first housing portion 11D and a second housing portion 12D, which are soldered together along with the heat dissipation plates 2D. The housing 1D is formed therein with a closed receiving space 13D.

The two heat dissipation plates 2D are stacked in the receiving space 13D in such a way that their flow channels 21D are angularly offset with respect to and overlap each other. The two heat dissipation plates 2D are each formed with a hollow flow channel 21D by stamping, and each of the two flow channels 21D has a continuous back-and-forth curvy shape. The two heat dissipation plates 2D are so stacked that the two flow channels 21D are perpendicular to and overlap each other, and that the overlapping portions of the two flow channels 21D form a hollow portion 24D. The hollow portion 24D is in communication with the first housing portion 11D and the second housing portion 12D. One of the flow channels 21D has one end configured as an input end 22D, which is in communication with a through hole of the housing 1D. A sealing tube 23D is inserted into the input end 22D so that a working fluid can be injected through the sealing tube 23D into the input end 22D before the sealing tube 23D is sealed.

To use this embodiment as a closed heat sink, with continued reference to FIG. 12 and FIG. 13, an outer surface of the first housing portion 11D is fixedly provided with a plurality of heat dissipation fins (see FIG. 4), and an outer surface of the second housing portion 12D is joined to a heat source from which heat is to be dissipated (see also FIG. 4). The heat generated by the heat source can be dissipated through the working fluid in the housing 1D in the same way as in the first embodiment; the heat dissipation process, therefore, will not be described repeatedly.

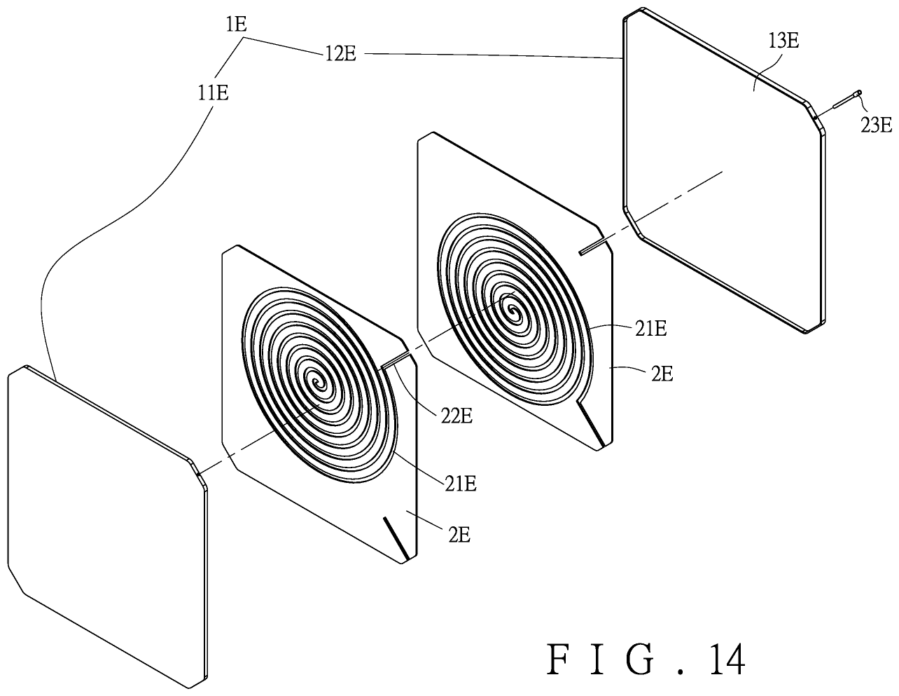

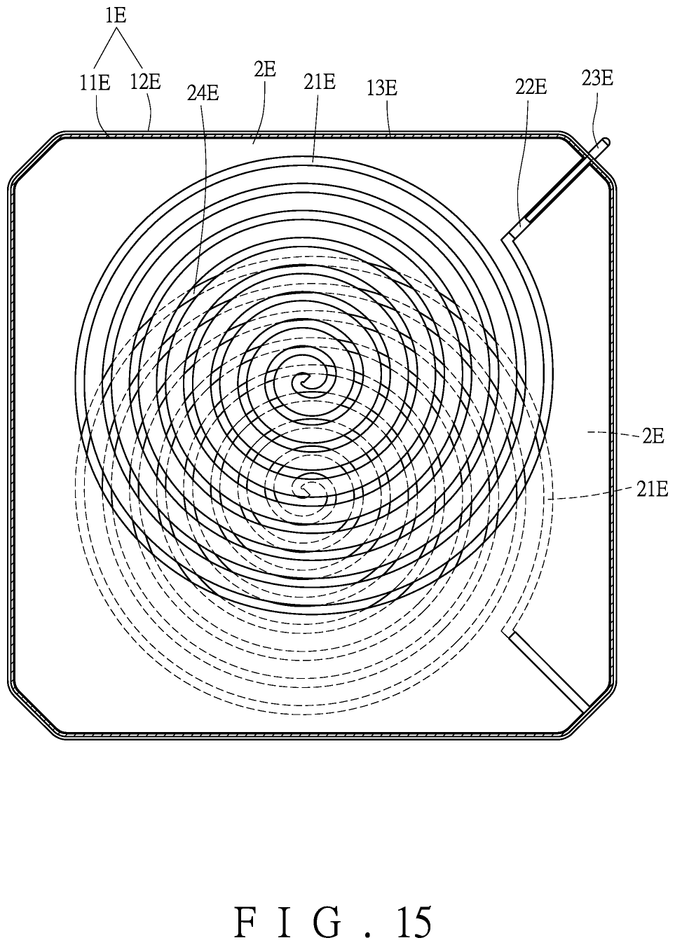

Please refer FIG. 14 and FIG. 15 for the sixth embodiment of the present invention.

The sixth embodiment includes a housing 1E and at least two heat dissipation plates 2E. The housing 1E includes a first housing portion 11E and a second housing portion 12E, which are soldered together along with the heat dissipation plates 2E. The housing 1E is formed therein with a closed receiving space 13E.

The two heat dissipation plates 2E are stacked in the receiving space 13E in such a way that their flow channels 21E are inverted with respect to and overlap each other. The two heat dissipation plates 2E are each formed with a hollow flow channel 21E by stamping, and each of the two flow channels 21E has a continuous circular spiral shape. The two heat dissipation plates 2E are so stacked that one of the two flow channels 21E is turned over, and linearly offset, with respect to and overlaps the other, and that the overlapping portions of the two flow channels 21E form a hollow portion 24E. The hollow portion 24E is in communication with the first housing portion 11E and the second housing portion 12E. One of the flow channels 21E has one end configured as an input end 22E, which is in communication with a through hole of the housing 1E. A sealing tube 23E is inserted into the input end 22E so that a working fluid can be injected through the sealing tube 23E into the input end 22E before the sealing tube 23E is sealed.

To use this embodiment as a closed heat sink, with continued reference to FIG. 14 and FIG. 15, an outer surface of the first housing portion 11E is fixedly provided with a plurality of heat dissipation fins (see FIG. 4), and an outer surface of the second housing portion 12E is joined to a heat source from which heat is to be dissipated (see also FIG. 4). The heat generated by the heat source can be dissipated through the working fluid in the housing 1E in the same way as in the first embodiment; the heat dissipation process, therefore, will not be described repeatedly.

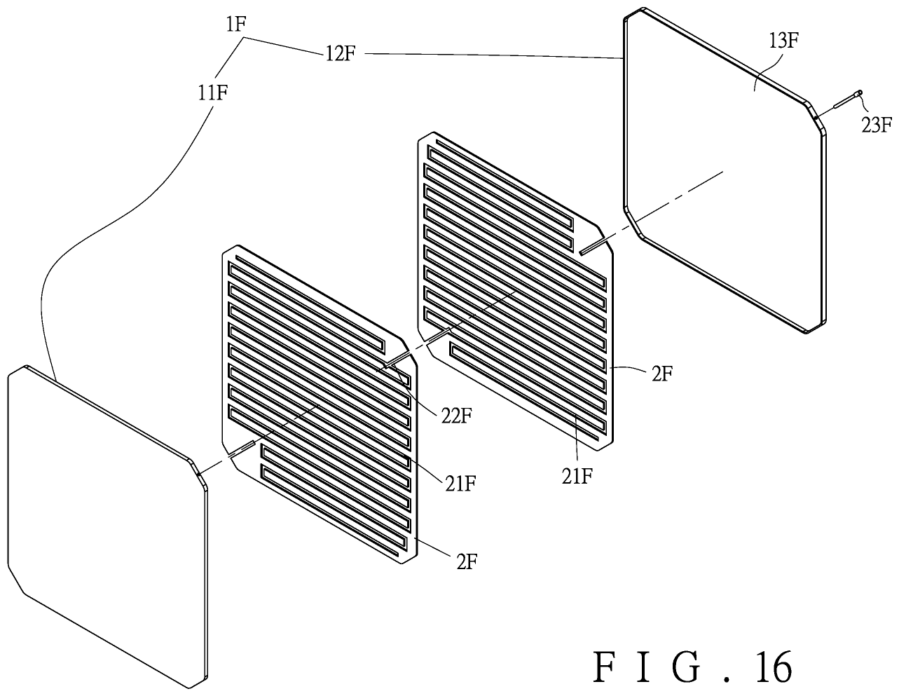

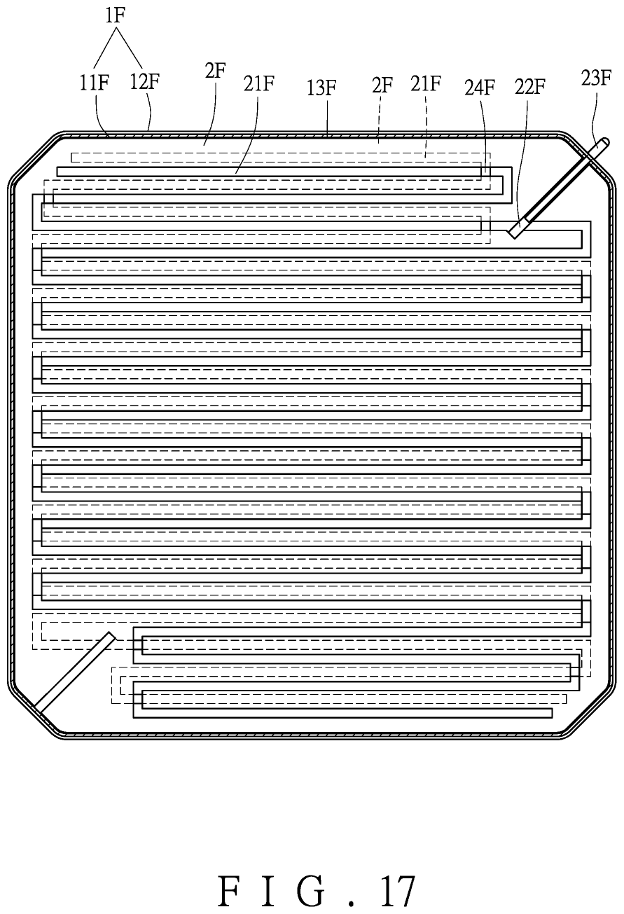

Please refer FIG. 16 and FIG. 17 for the seventh embodiment of the present invention.

The seventh embodiment includes a housing 1F and at least two heat dissipation plates 2F. The housing 1F includes a first housing portion 11F and a second housing portion 12F, which are soldered together along with the heat dissipation plates 2F. The housing 1F is formed therein with a closed receiving space 13F.

The two heat dissipation plates 2F are stacked in the receiving space 13F in such a way that their flow channels 21F are inverted with respect to and overlap each other. The two heat dissipation plates 2F are each formed with a hollow flow channel 21F by stamping, and each of the two flow channels 21F has a continuous back-and-forth wavy shape. The two heat dissipation plates 2F are so stacked that one of the two flow channels 21F is turned upside down (i.e., angularly offset by 180°), and also linearly offset, with respect to and overlaps the other, and that the overlapping portions of the two flow channels 21F form a hollow portion 24F. The hollow portion 24F is in communication with the first housing portion 11F and the second housing portion 12F. One of the flow channels 21F has one end configured as an input end 22F, which is in communication with a through hole of the housing 1F. A sealing tube 23F is inserted into the input end 22F so that a working fluid can be injected through the sealing tube 23F into the input end 22F before the sealing tube 23F is sealed.

To use this embodiment as a closed heat sink, with continued reference to FIG. 16 and FIG. 17, an outer surface of the first housing portion 11F is fixedly provided with a plurality of heat dissipation fins (see FIG. 4), and an outer surface of the second housing portion 12F is joined to a heat source from which heat is to be dissipated (see also FIG. 4). The heat generated by the heat source can be dissipated through the working fluid in the housing 1F in the same way as in the first embodiment; the heat dissipation process, therefore, will not be described repeatedly.

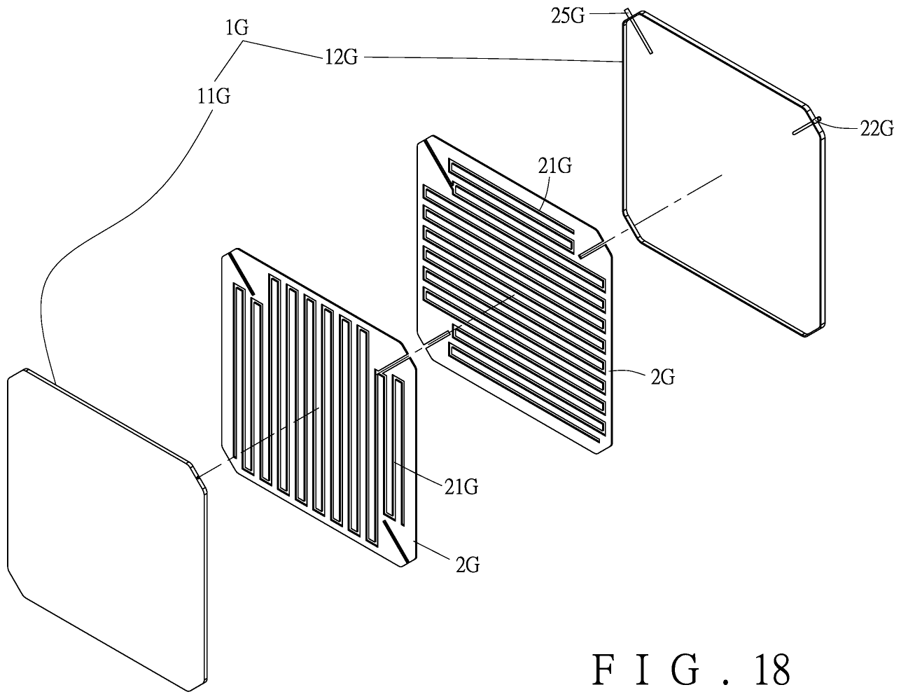

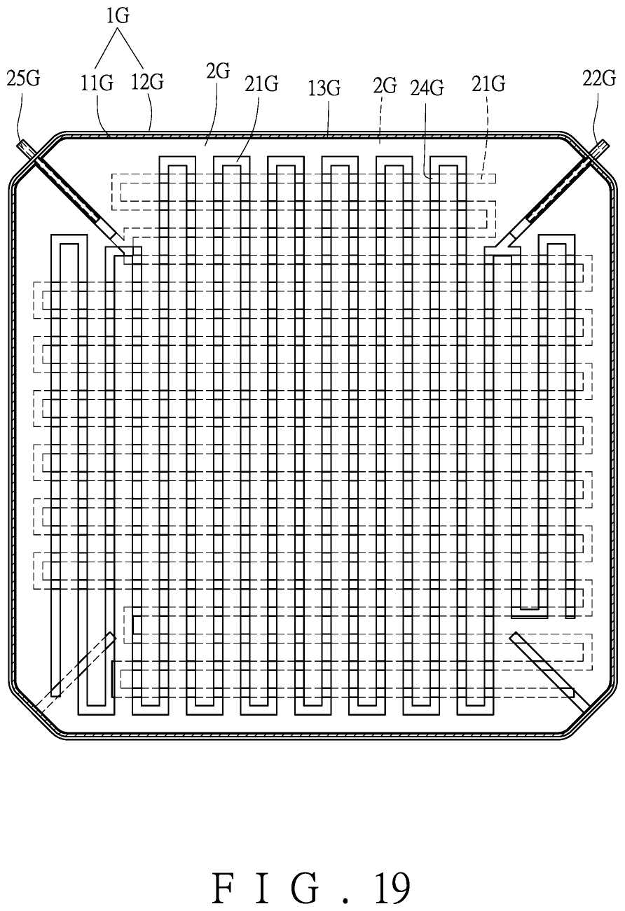

Please refer FIG. 18 and FIG. 19 for the eighth embodiment of the present invention.

The eighth embodiment includes a housing 1G and at least two heat dissipation plates 2G. The housing 1G includes a first housing portion 11G and a second housing portion 12G, which are soldered together along with the heat dissipation plates 2G. The housing 1G is formed therein with a closed receiving space 13G.

The two heat dissipation plates 2G are stacked in the receiving space 13G in such a way that their flow channels 21G are angularly offset with respect to and overlap each other. The two heat dissipation plates 2G are each formed with a hollow flow channel 21G by stamping, and each of the two flow channels 21G has a continuous back-and-forth wavy shape. The two heat dissipation plates 2G are so stacked that the two flow channels 21G are perpendicular to and overlap each other, and that the overlapping portions of the two flow channels 21G form a hollow portion 24G. The hollow portion 24G is in communication with the first housing portion 11G and the second housing portion 12G. The flow channel 21G of one of the heat dissipation plates 2G has one end that is in communication with a through hole of the housing 1G and connected to an input end 22G so that a working fluid, which may be a refrigerant or water, can be injected into the input end 22G and flow in the two flow channels 21G. The flow channel 21G of the other heat dissipation plate 2G has one end that is in communication with another through hole of the housing 1G and connected to an output end 25G through which to output the working fluid.

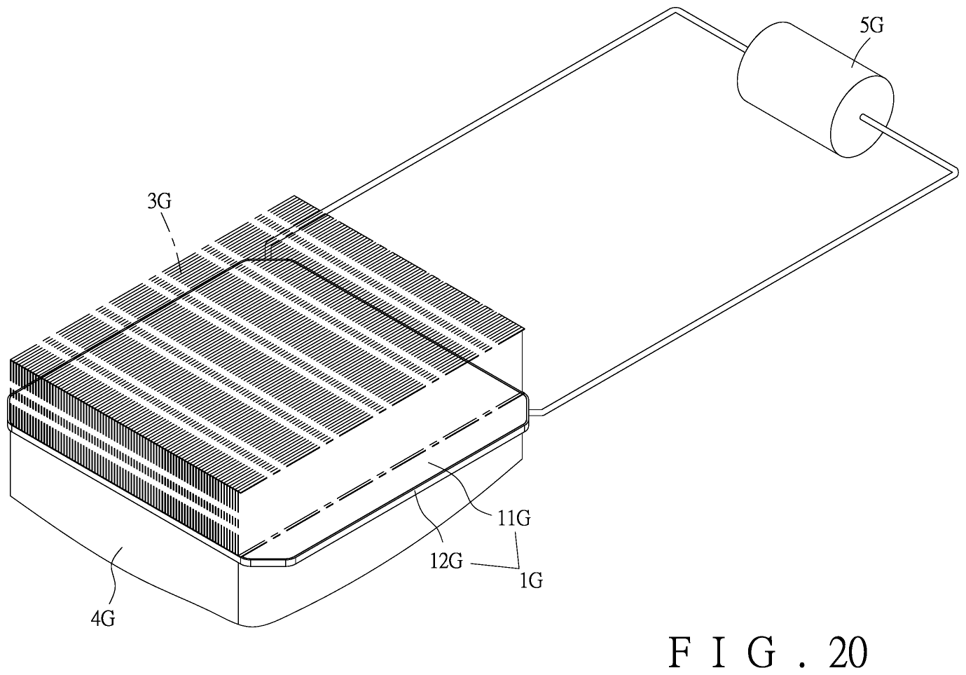

To use this embodiment as an open heat sink, referring to FIG. 19 and FIG. 20, an outer surface of the first housing portion 11G is fixedly provided with a plurality of heat dissipation fins 3G, and an outer surface of the second housing portion 12G is joined to a heat source 4G from which heat is to be dissipated. The input end 22G and the output end 25G are connected to a pump 5G. The pump 5G can generate a pressure that causes the working fluid to flow through the input end 22G into the receiving space 13G. As the working fluid accumulates, turbulent flow is generated in the flow channels 21G (both of which have a continuous back-and-forth wavy shape), and the working fluid is circulated between the first housing portion 11G and the second housing portion 12G, flows to the inner side of each housing portion 11G or 12G through the hollow portion 24G, and can therefore make sufficient contact with both housing portions 11G and 12G to conduct the heat generated by the heat source 4G to the heat dissipation fins 3G on the outer surface of the first housing portion 11G. The working fluid is thus cooled by heat exchange between the heat dissipation fins 3G and the relatively low-temperature ambient air, and the cooled working fluid flows through the output end 25G into the pump 5G and then back into the receiving space 13G to continue dissipating heat from the heat source 4G.

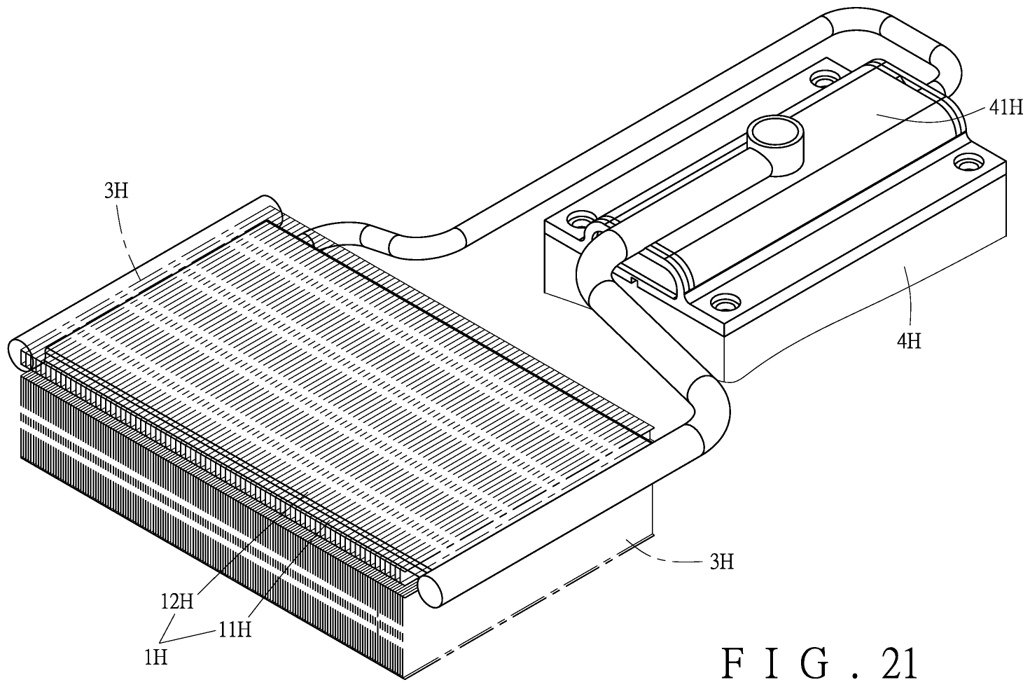

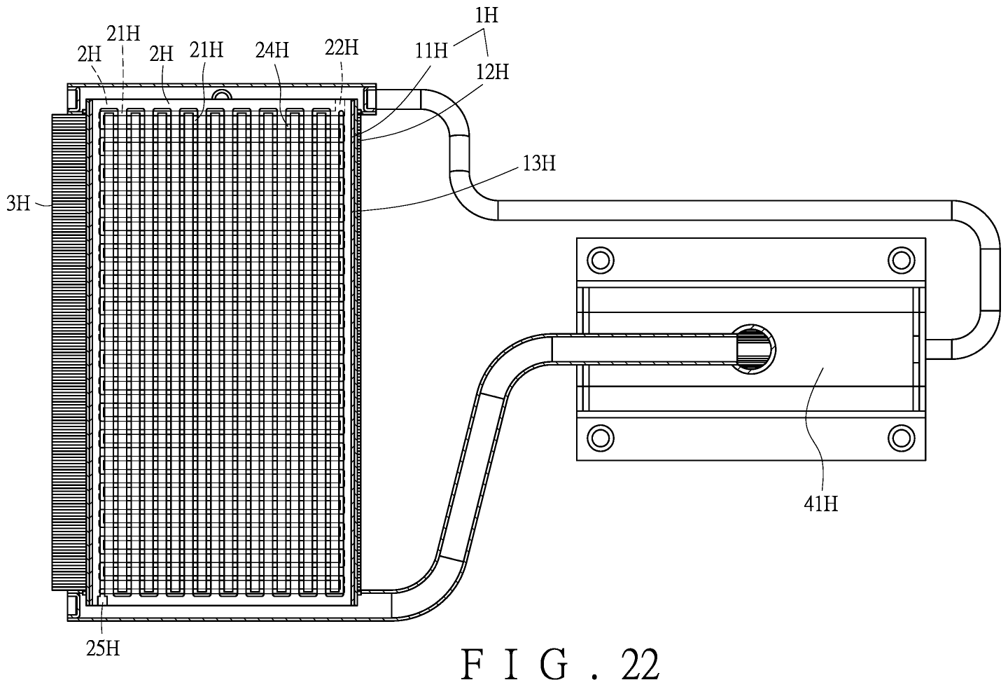

Please refer FIG. 21 and FIG. 22 for the ninth embodiment of the present invention.

The ninth embodiment includes a housing 1H and at least two heat dissipation plates 2H. The housing 1H includes a first housing portion 11H and a second housing portion 12H, which are soldered together along with the heat dissipation plates 2H. The housing 1H is formed therein with a closed receiving space 13H.

The two heat dissipation plates 2H are stacked in the receiving space 13H in such a way that their flow channels 21H are angularly offset with respect to and overlap each other. The two heat dissipation plates 2H are each formed with a hollow flow channel 21H by stamping, and each of the two flow channels 21H has a continuous back-and-forth wavy shape. The two heat dissipation plates 2H are so stacked that the two flow channels 21H are perpendicular to and overlap each other, and that the overlapping portions of the two flow channels 21H form a hollow portion 24H. The hollow portion 24H is in communication with the first housing portion 11H and the second housing portion 12H. The flow channel 21H of one of the heat dissipation plates 2H has one end configured as an input end 22H, which is in communication with a through hole of the housing 1H so that a working fluid, which may be a refrigerant or water, can be injected into the input end 22H and flow in the two flow channels 21H. The flow channel 21H of the other heat dissipation plate 2H has one end configured as an output end 25H, which is in communication with another through hole of the housing 1H so that the working fluid can be output through the output end 25H.

To use this embodiment as a closed heat sink, with continued reference to FIG. 21 and FIG. 22, an outer surface of the first housing portion 11H is fixedly provided with a plurality of heat dissipation fins 3H, and so is an outer surface of the second housing portion 12H. The input end 22H and the output end 25H are connected to the heat dissipation unit 41H of a heat source 4H so that the heat generated by the heat source 4H can be dissipated through the working fluid in the housing 1H in the same way as in the first embodiment; the heat dissipation process, therefore, will not be described repeatedly.

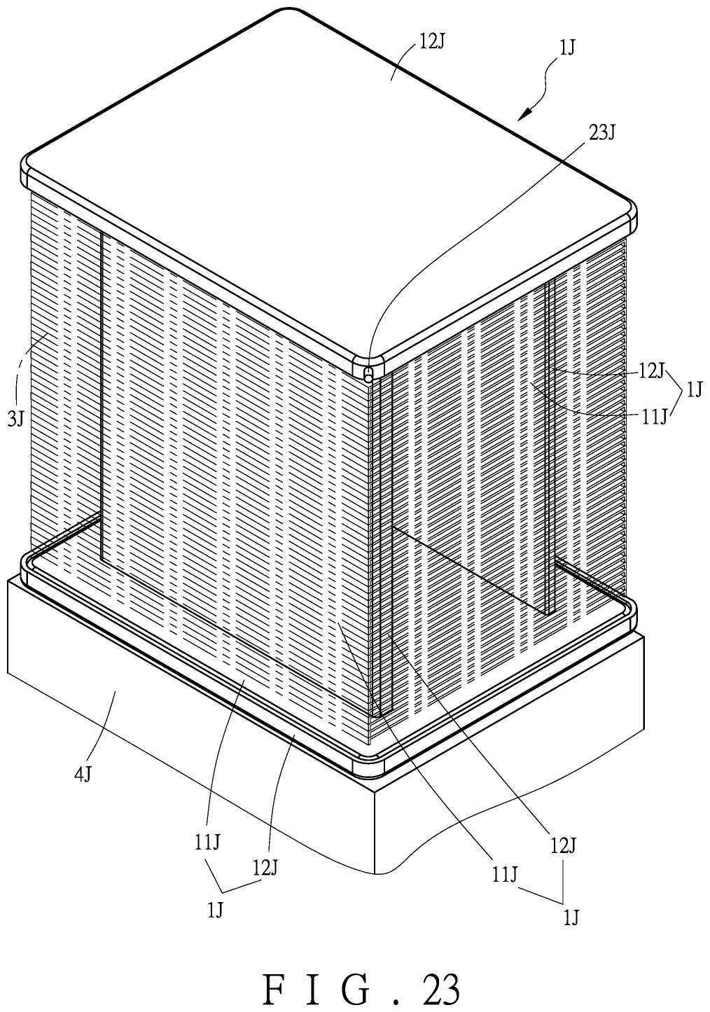

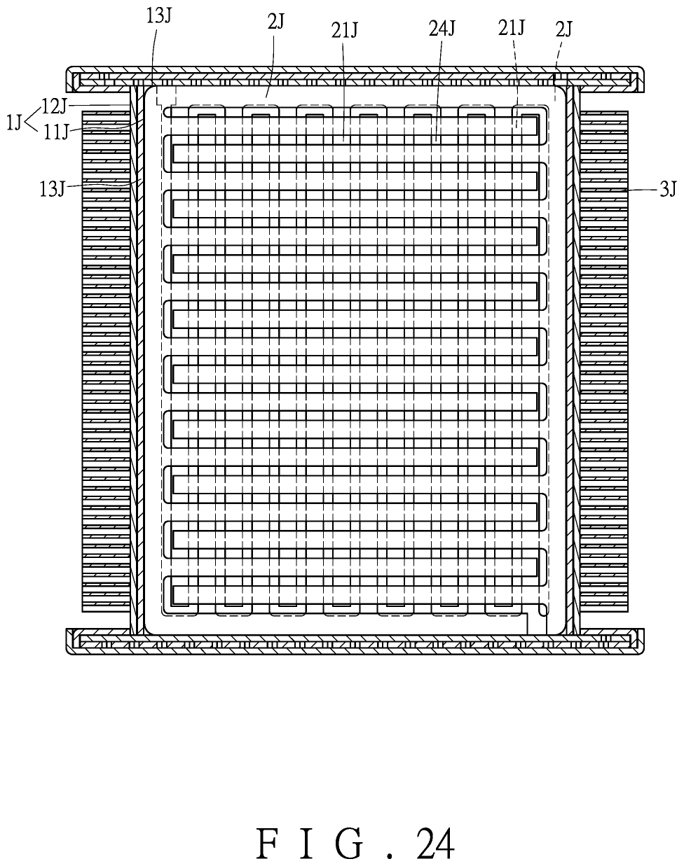

Please refer FIG. 23 and FIG. 24 for the tenth embodiment of the present invention.

The tenth embodiment includes a housing 1J and at least two heat dissipation plates 2J. The housing 1J includes a first housing portion 11J and a second housing portion 12J, which are soldered together along with the heat dissipation plates 2J. The housing 1J is formed therein with a closed receiving space 13J.

The two heat dissipation plates 2J are stacked in the receiving space 13J in such a way that their flow channels 21J are angularly offset with respect to and overlap each other. The two heat dissipation plates 2J are each formed with a hollow flow channel 21J by stamping, and each of the two flow channels 21H has a continuous back-and-forth wavy shape. The two heat dissipation plates 2J are so stacked that the two flow channels 21J are perpendicular to and overlap each other, and that the overlapping portions of the two flow channels 21J form a hollow portion 24J. The hollow portion 24J is in communication with the first housing portion 11J and the second housing portion 12J.

To use this embodiment as a closed heat sink, with continued reference to FIG. 23 and FIG. 24, four housings 1J are connected to make up a vertical structure, with the receiving spaces 13J in the four housings 1J in communication with one another to form a circulatory heat dissipation loop. The flow channel 21J in one of the housings 1J has one end configured as an input end (not shown), which is in communication with a through hole of the housing 1J, and a sealing tube 23J is inserted into the input end so that a working fluid can be injected through the sealing tube 23J into the input end before the sealing tube 23J is sealed, wherein the working fluid is intended to circulate in the flow channels 21J in the four housings 1J. In addition, a plurality of heat dissipation fins 3J are fixedly provided between the four housings 1J, and one of the housings 1J has an outer surface joined to a heat source 4J. The heat generated by the heat source 4J is transmitted through this housing 1J to the working fluid in the flow channels 21J as heat exchange takes place between the heat source 4J and the working fluid. Once the heat is accumulated in the working fluid, turbulent flow is generated in the flow channels 21J (all of which have a continuous back-and-forth wavy shape), and the working fluid is circulated between the four housings 1J. The heat carried by the working fluid is thus conducted to the heat dissipation fins 3J, which exchange heat with the relatively low-temperature ambient air to dissipate the heat of the heat source 4J to the surroundings.

The embodiments described above shall be able to enable a full understanding of the operation, use, and effects of the present invention. The foregoing embodiments, however, are only some preferred ones of the invention and are not intended to be restrictive of the scope of the invention. All equivalent changes and modifications that can be easily derived from the appended claims and the disclosure of this specification shall fall within the scope of the invention.

What is claimed is:

1. A thin heat sink structure, comprising:
a housing comprising and assembled from a first housing portion and a second housing portion, the housing being formed therein with a receiving space; and
at least one heat dissipation plate provided in the receiving space, the heat dissipation plate being formed with at least one hollow flow channel in communication with the first housing portion and the second housing portion.

2. The thin heat sink structure of claim 1, wherein there are at least two said heat dissipation plates, and the two heat dissipation plates are stacked in the receiving space in such a way that the flow channel of one of the heat dissipation plates is linearly or angularly offset with respect to and overlaps the flow channel of the other heat dissipation plate, and that overlapping portions of the two flow channels form a hollow portion in communication with the first housing portion and the second housing portion.

3. The thin heat sink structure of claim 2, wherein the two heat dissipation plates are stacked in such a way that the flow channel of one of the heat dissipation plates is at 90° with (i.e., perpendicular to) or at 180° with (i.e., turned over or upside down with respect to) the flow channel of the other heat dissipation plate.

4. The thin heat sink structure of claim 2, wherein the at least one flow channel of each said heat dissipation plate is one or an arbitrary combination of a continuous back-and-forth wavy-shaped flow channel, a continuous and slanting back-and-forth wavy-shaped flow channel, a plurality of rows of slantingly arranged and spaced-apart H-shaped flow channels, a continuous back-and-forth curvy-shaped flow channel, and a continuous circular spiral-shaped flow channel.

5. The thin heat sink structure of claim 1, wherein the first housing portion is fixedly provided with a plurality of heat dissipation fins, and the second housing portion is joined to a heat source.

6. The thin heat sink structure of claim 2, wherein the flow channel of one of the heat dissipation plates has one end configured as an input end, and the input end is in communication with a through hole of the housing so that a working fluid is able to be input into the input end in order to flow in the flow channels and contact the first housing portion and the second housing portion.

7. The thin heat sink structure of claim 6, wherein the flow channel of the other heat dissipation plate has one end configured as an output end, and the output end is in communication with another through hole of the housing so that the working fluid is able to be output through the output end.

8. The thin heat sink structure of claim 7, wherein the first housing portion is fixedly provided with a plurality of heat dissipation fins, the second housing portion is joined to a heat source, and the input end and the output end are connected to a pump to enable circulation of the working fluid between an interior of the housing and the pump.

9. The thin heat sink structure of claim 2, wherein four said housings are connected to form a vertical structure, and the receiving spaces in the four housings are in communication with one another to form a circulatory heat dissipation loop.

10. The thin heat sink structure of claim 1, wherein the first housing portion, the second housing portion, and the heat dissipation plate are soldered together, and the flow channel of the heat dissipation plate is formed by stamping.
